(19) United States
(12) Patent Application Publication
(10) Pub. No.: US 2026/0202462 A1
(43) Pub. Date: Jul. 16, 2026

(54) INTELLIGENT CAMERA-DRIVEN MEASUREMENT SETUP AND DATA INTEGRATION TOOL

(71) Applicant: KEYSIGHT TECHNOLOGIES, INC., Santa Rosa, CA (US)

(72) Inventor: Maxim Pletner, Santa Clara, CA (US)

(21) Appl. No.: 19/423,554

(22) Filed: Dec. 17, 2025

Related U.S. Application Data
(60) Provisional application No. 63/744,047, filed on Jan. 10, 2025.

(51) Int. Cl. G01R 31/28; G06T 7/00

(52) U.S. Cl. CPC G01R 31/2834; G06T 7/0004

(57) ABSTRACT

A system for automated device-under-test (DUT) recognition and measurement setup includes a camera configured to capture an image of a DUT, an image analyzer configured to process the captured image and extract DUT characteristics, a large language model (LLM) system configured to identify the DUT based on the extracted characteristics and retrieve DUT specifications, a command processing module configured to generate measurement setup commands based on the retrieved DUT specifications, and a network analyzer configured to execute the measurement setup commands for testing the DUT.

### CROSS-REFERENCE TO RELATED APPLICATION

The present application claims priority under 35 U.S.C. § 119(e) to U.S. Provisional Application No. 63/744,047 filed on January 10, 2025. The entire disclosure of U.S. Provisional Application No. 63/744,047 is specifically incorporated herein by reference in its entirety.

### FIELD

The present disclosure relates to automated test and measurement systems, and more particularly to a system for intelligent device recognition and measurement setup in radio frequency and microwave testing using vector network analyzers.

### BACKGROUND

In the field of radio frequency (RF) and microwave testing, vector network analyzers (VNAs) are essential instruments for characterizing the performance of various devices and components. These analyzers measure the magnitude and phase of transmitted and reflected signals, providing critical information about a device's behavior across a range of frequencies.

As technology advances, the complexity and variety of devices under test (DUTs) continue to increase. This evolution presents challenges for test engineers who must efficiently and accurately configure measurement setups for each unique DUT. Traditional methods often rely on manual configuration of instruments, which can be time-consuming and prone to errors.

The process of setting up a VNA for testing typically involves several steps, including calibration, frequency range selection, power level adjustment, and measurement parameter configuration. Each of these steps requires careful consideration of the specific DUT's characteristics and the desired measurement outcomes. Moreover, as the number and types of DUTs grow, maintaining consistent and repeatable test procedures becomes increasingly difficult.

Engineers often create custom templates or state files for different measurement scenarios, but these may require modification for each new DUT. The lack of a standardized approach to test setup can lead to inconsistencies in measurement results and increased time spent on configuration rather than analysis.

Furthermore, the interpretation and application of DUT specifications from datasheets to instrument settings is a critical step that demands expertise and attention to detail. Misinterpretation or overlooking of key parameters can result in inaccurate measurements or potentially damaging test conditions for sensitive devices.

### SUMMARY

According to an aspect of the inventive concepts, a system for automated device-under-test (DUT) recognition and measurement setup is provided. The system includes a camera configured to capture an image of a DUT, an image analyzer configured to process the captured image and extract DUT characteristics, a large language model (LLM) system configured to identify the DUT based on the extracted characteristics and retrieve DUT specifications, a command processing module configured to generate measurement setup commands based on the retrieved DUT specifications, and a network analyzer configured to execute the measurement setup commands for testing the DUT.

The LLM system may be further configured to retrieve measurement conditions for the DUT from a datasheet or database. In this case, the measurement conditions may include frequency ranges, power limits, and operational parameters specific to the identified DUT.

The command processing module may be further configured to generate SCPI (Standard Commands for Programmable Instruments) commands based on the retrieved DUT specifications. In this case, the command processing module may be further configured to access a command repository containing SCPI command syntax for various network analyzers.

The system may further include a user interface configured to display the extracted DUT characteristics and allow user confirmation or modification of the identified DUT. In this case, the user interface may be further configured to display and allow user selection of pre-configured measurement setups or state files associated with the identified DUT.

According to another aspect of the inventive concepts, a method for automated device-under-test (DUT) recognition and measurement setup is provided. The method includes capturing an image of a DUT using a camera, analyzing the captured image to extract DUT characteristics, identifying the DUT and retrieving DUT specifications using a large language model (LLM) system based on the extracted characteristics, generating measurement setup commands based on the retrieved DUT specifications, and configuring a network analyzer using the generated measurement setup commands for testing the DUT.

The method may further include retrieving measurement conditions for the DUT from a datasheet or database using the LLM framework. In this case, the measurement conditions may include frequency ranges, power limits, and operational parameters specific to the identified DUT.

Generating measurement setup commands may include generating SCPI (Standard Commands for Programmable Instruments) commands based on the retrieved DUT specifications. In this case, the method may further include accessing a command repository containing SCPI command syntax for various network analyzers.

The method may further include displaying the extracted DUT characteristics on a user interface and allowing user confirmation or modification of the identified DUT. In this case, the method may further include displaying and allowing user selection of pre-configured measurement setups or state files associated with the identified DUT.

According to still another aspect of the inventive concepts, a non-transitory computer-readable medium storing instructions is provided that, when executed by a processor, cause the processor to perform operations for automated device-under-test (DUT) recognition and measurement setup. The operations include receiving a captured image of a DUT, extracting DUT characteristics from the captured image, identifying the DUT and retrieving DUT specifications using a large language model (LLM) system based on the extracted characteristics, generating measurement setup commands based on the retrieved DUT specifications, and sending the generated measurement setup commands to a network analyzer for configuring the network analyzer to test the DUT.

The operations may further include retrieving measurement conditions for the DUT from a datasheet or database using the LLM framework. In this case, the measurement conditions may include frequency ranges, power limits, and operational parameters specific to the identified DUT.

The generation of measurement setup commands may include generating SCPI (Standard Commands for Programmable Instruments) commands based on the retrieved DUT specifications. In this case, the operations may further include accessing a command repository containing SCPI command syntax for various network analyzers.

The operations may further include displaying the extracted DUT characteristics on a user interface and allowing user confirmation or modification of the identified DUT.

### BRIEF DESCRIPTION OF THE DRAWINGS

The above and other aspects and features of the inventive concepts will become readily apparent from the detailed description that follows, with reference to the accompanying drawings, in which:

FIG. 1 is a hybrid system/ flow diagram for automated device-under-test (DUT) recognition and measurement setup in according to embodiments of the inventive concepts.

FIG. 2 shows an example of a Main Application Screen in an initial state of a network analyzer, and FIG. 3 shows an example of the Main Application Screen of the fully configured Network Analyzer after the recognition framework has been applied, according to embodiments of the inventive concepts;

FIG. 4 through 11 are example screen shots for reference in describing a SCPI user guide breakdown, a vectorization process and a RAG (Retrieve-then-Generate) approach according to embodiments of the inventive concepts;

FIGS. 12 through 15 are screen shots for reference in describing machine-user communication and interface integration according to embodiments of the inventive concepts; and

FIGS. 16 through 21 are screen shots for reference in describing an automated framework implementation using PathWave ® Test Automation in accordance with embodiments of the inventive concepts.

### DETAILED DESCRIPTION

In the following detailed description, for purposes of explanation and not limitation, representative embodiments disclosing specific details are set forth in order to provide a thorough understanding of the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparatuses and methods may be omitted to avoid obscuring the description of the example embodiments. Such methods and apparatuses are clearly within the scope of the present teachings. Further, throughout the drawings, like reference numbers refer to the same or similar elements.

The terminology used herein is for purposes of describing particular embodiments only, and is not intended to be limiting. The defined terms are in addition to the technical and scientific meanings of the defined terms as commonly understood and accepted in the technical field of the present teachings. As used in the specification and appended claims, the terms ‘a’, ‘an’ and ‘the’ include both singular and plural referents, unless the context clearly dictates otherwise. Thus, for example, ‘a device’ includes one device and plural devices. Further, for example, when one element is described as being “connected to” another element, the one element may be directly connected to the other element, or indirectly connected to the other element in an operative manner.

Separately, as is traditional in the field of the inventive concepts, example embodiments may be described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, and the like, which may be formed using semiconductor-based fabrication techniques or other manufacturing technologies. In the case of the blocks, in the absence of an indication to the contrary, the units and/or modules being implemented by microprocessors or similar may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions. Also, each block, unit and/or module of the example embodiments may be physically separated into two or more interacting and discrete blocks, units and/or modules without departing from the scope of the example embodiments. Conversely, the blocks, units and/or modules of the example embodiments may be physically combined into more complex blocks, units and/or modules without departing from the scope of the example embodiments.

In RF/mm-wave testing especially with Vector Network Analyzers (VNA), test engineers face the challenge of tracking specific details for each Device-Under-Test (DUT), essential for its transparent identification and characterization. Engineers often rely on manually created naming conventions or other methods to remember what occurred during tests, as there is no standardized test setup or state file for different measurements. This forces them to configure instruments or develop state files on a case-by-case basis, demanding extensive attention to accurately differentiate and label each test. Ensuring repeatability requires either manually repeating measurement steps or using pre-made test plans or automation routines, both of which still necessitate careful control to maintain accuracy. Furthermore, engineers must explicitly identify the specific DUT to avoid potential confusion, making the process labor-intensive and susceptible to errors. The invention concepts provide an intelligent, camera-driven technical solution to automatically recognize DUTs, retrieve related specifications, and configure the measurement setups accordingly, streamlining the process, reducing cognitive load, and enhancing efficiency and consistency in test and measurement tasks.

Currently engineers working without prior automation preparation or using a preset instrument must manually track DUT details using naming conventions that include the DUT ID, sample number, and relying on a very limited trace data headers for measurement types and conditions. They often create templates from scratch or carefully modify generalized templates, each time ensuring they align with the exact DUT specifications, which is time-consuming and prone to error. Additionally, there are no built-in tools to automatically check if the measurement mode matches the DUT datasheet especially when testing against limits, which must be read from datasheets and imported using specific syntax of network analyzer applications. Most of the instruments usually don’t have the capability to automatically save photos of the DUT, which could aid in documenting and verifying setups. Moreover, engineers are required to manage repeatability through manual steps or by using custom automation routines, but this still requires extensive oversight to differentiate and label measurements correctly.

That is, current technology requires engineers to rely on manual naming conventions and setup processes, the increasing the likelihood of errors and reducing test speed / data reuse. Further, each measurement often requires engineers to create or verify templates manually, which takes significant time and effort. Additionally, instruments do not provide automated alignment of the measurement modes and limits with the DUT’s datasheet, leaving room for setup errors. Current technologies are devoid of an automated way to collect comprehensive measurement data, including images, trace files, and DUT specifications, making it harder to document the testing process. And, engineers cannot easily access external databases or use internet resources to pull in relevant datasheets or additional contextual information for their tests within the same test and measurement environment.

As will become apparent below, the inventive concepts offer a number of technological solutions to the aforementioned hurdles currently faced by engineers. Without intending to limit the scope of the inventive concepts, a brief description of at least some of these technological solutions are enumerated below:

1. Automated DUT Identification and Setup: The camera-driven system automatically identifies the DUT, retrieves specifications, and configures the instrument, eliminating manual input and reducing errors.

2. Fast and Accurate Template Configuration: The system may apply preconfigured templates based on retrieved DUT data, drastically reducing the time needed for manual template creation or verification.

3. Quick Test Parametrization: The system set up the measurement mode to be properly aligned with the DUT’s datasheet in three automated steps, improving measurement accuracy.

4. Automatic Import of Limits: The system imports operational limits directly from the DUT datasheet, reducing manual configuration time and preventing errors.

5. Enhanced Data Collection: The solution captures and stores a wide array of data, including images, trace files, and specifications, making it easier to document and analyze measurements.

6. Internal Database and Online Sources Integration: The system can access internal databases and perform internet searches to retrieve relevant datasheets and contextual information, ensuring accurate and up-to-date measurement configurations.

7. Improved Compatibility: By default, the functionality may be installed within the Network Analyzer measurement software (e.g., from Keysight ® Technologies) calling a precompiled automation routine. Injecting additional SCPI programming guides allows use of the framework with 3^{rd} party instruments with the help of, for example, PathWave® Test Automation infrastructure.

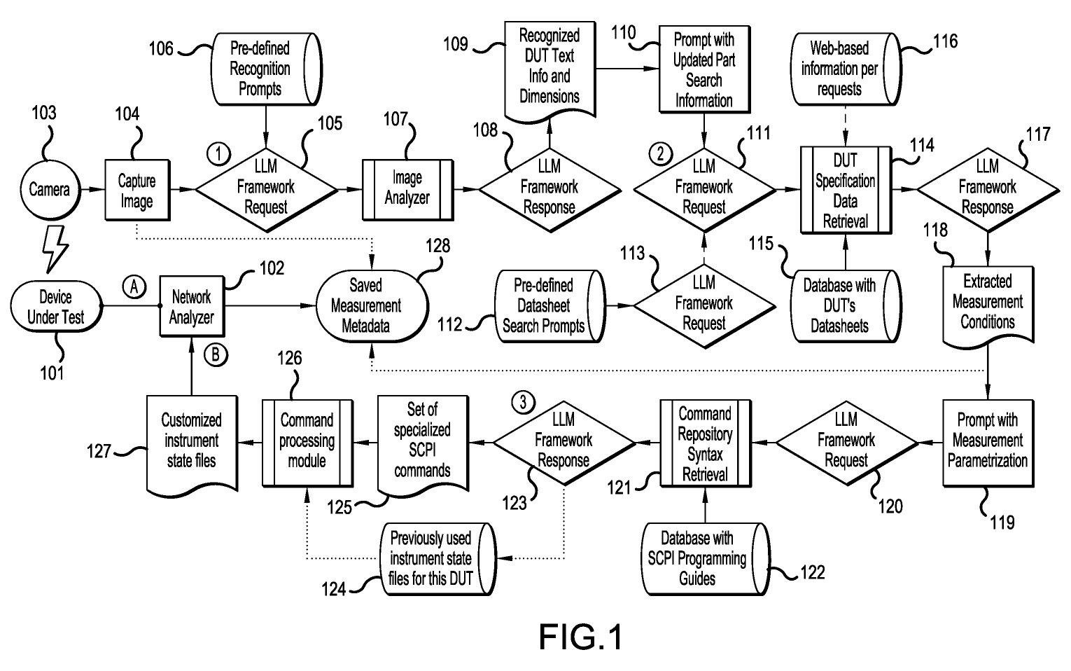

FIG. 1 is a hybrid system/ flow diagram for automated device-under-test (DUT) recognition and measurement setup in according with Embodiments of the inventive concepts.

In FIG. 1, the circled letters A and B represent the instrument's main application screen before and after calling the recognition framework (preset instrument state and fully configured customized state), respectively. Also in FIG. 1, the circled numbers 1, 2 and 3 indicate customer interaction points with the LLM framework, where the user engages with the system to provide additional input or confirmation.

The DUT recognition framework and step-by-step procedure will be described next in connection with FIG. 1. In the figure, reference number 101 denotes the DUT, reference number 102 denotes a network analyzer, and reference number 103 denotes a camera

The remaining elements of the figure represent the framework for automating recognition of the DUT 101 and configuring the measurement setup of the network analyzer 102. As will be explained below, By leveraging AI and database integration, the system identifies the DUT, retrieves relevant specifications, configures the instrument accordingly, and automates the setup process

### 1. Camera Capture 104 of FIG. 1

The process begins when the camera captures an image of the Device Under Test (DUT). This image is then sent to the Image Analyzer for further processing.

### 2. LLM Framework Request - Recognition Step 1 of Machine-User Interaction 105 and 106 of FIG. 1

The system generates a request for the LLM Framework, operating either in online or offline mode (which determines the location of a server in an API call) to analyze the captured image using pre-defined recognition prompts. The focus is on identifying text, dimensions, and other relevant DUT information.

### 3. Image Analysis 107 of FIG. 1

The Image Analyzer processes the captured image, extracting specific DUT characteristics such as text identifiers and physical dimensions. The call to the image analyzer is made through the LLM framework, which improves the quality of the retrieved information using contextual features.

As part of this procedure, a basic check on the cables is conducted by comparing the visual representation of the captured image with stored cable image patterns.

### 4. LLM FRAMEWORK RESPONSE - DUT IDENTIFICATION 108, 109 AND 110 OF FIG. 1

The LLM Framework responds with the recognized DUT information, including text identifiers and dimensions.

The system generates a prompt with updated part information or performs a search to retrieve more details about the DUT, such as part numbers and specifications.

### 5. LLM Framework Request - Datasheet Retrieval Step 2 of Machine - User Interaction 111, 112 and 113 of FIG. 1

A second request is made by the LLM Framework to retrieve and process relevant specifications for the DUT from either an internal database of datasheets or through an internet search. If needed, the user can also manually import datasheets.

### 6. DUT Specification Data Retrieval 114, 115 and 116 of FIG. 1

The system pulls essential DUT specifications, including measurement conditions, operational limits, frequency ranges, and other parameters necessary for configuring the Network Analyzer.

### 7. LLM Framework Response - Measurement Conditions 117, 118 and 199 of FIG. 1

The LLM Framework responds with the extracted measurement conditions, confirming that the system has retrieved all necessary DUT data to ensure proper test setup.

This measurement conditions are appended to the prompt with measurement parameterization, to make sure correct SCPI numerical parts and mode limits would be generated for the measurement state file in the end.

### 8. LLM Framework Request - Customized Command Repository Syntax Retrieval 120, 121 and 122 of FIG. 1

At this stage, the system generates another LLM Framework Request to retrieve the appropriate SCPI commands from a command repository. These SCPI commands correspond to the DUT’s measurement modes.

The command repository is a database that stores SCPI command syntax for various network analyzers, allowing for 3^{rd} party instruments support and future capabilities enhancements.

### 9. LLM Framework Response - Updated SCPI commands created with specific numerical values Step 3 of Machine-User Interaction 123, 124 and 125 of FIG. 1

After processing the commands, the LLM Framework generates a response that includes the updated SCPI commands alongside the related state files if found in the library.

### 10. Command Processing Module 126 and 127 of FIG. 1

At this point, the user can verify the measurement conditions (if no previous state files were found) or choose between the found state file.

The Command Processing Module converts the retrieved SCPI commands into test sequencies for the Network Analyzer. This process ensures that the instrument can perform the proper configured tests within relevant measurement modes based on the DUT’s specifications. During this process limits are loaded in the measurement FW.

This conversion is facilitated using the PathWave Test Automation toolset, which sends the commands to the instrument’s firmware.

The processed commands are used to create Customized Instrument State Files, which configure the Network Analyzer according to the exact requirements of the DUT.

### 11. Execution and Metadata Storage 102 and 128 of FIG. 1

The Network Analyzer executes the measurement using the customized state files and SCPI commands provided by the Command Processing Module.

The system automatically saves all relevant measurement metadata, including configuration details, captured photos, instrument states, and test results, to ensure future repeatability.

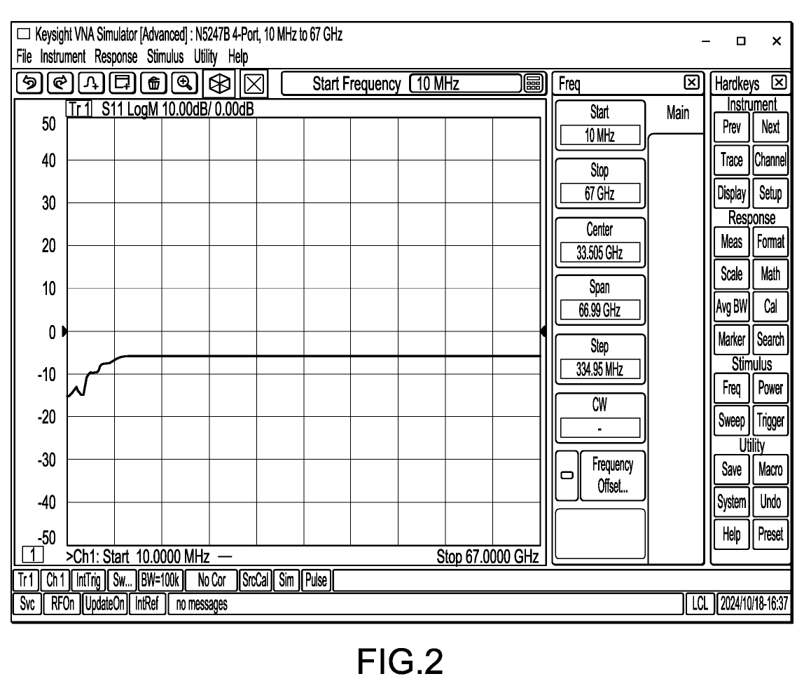

FIG. 2 shows an example of a Main Application Screensd in an initial state of the Network Analyzer 102 before applying the recognition framework, typically displaying a default factory setup.

FIG. 3 shows an example of the Main Application Screen of the fully configured Network Analyzer after the recognition framework has been applied, with the correct DUT-specific setup and limits applied during the tests (for Pass/Fail tests).

The LLM Framework Construction according to embodiments of the inventive concepts will be discussed next.

The LLM Framework plays a central role in the automated identification and configuration of measurement setups for Network Analyzers. The LLM Framework allows an access to the Image Analyzer (usually embedded within online deployments), analyzes the decoded text based on the context, retrieves relevant SCPI command information. The framework may integrate directly with both internal and external online resources and utilizes the RAG (Retrieve-then-Generate) approach for efficient information handling. The LLM framework is designed to interact with multiple data sources, including:

A database of DUT specifications.

External datasheets retrieved from the web.

Vectorized SCPI user guides for configuring the Network Analyzer.

Existing SCPI sequencies / .csa-state files for the found DUT part or type.

For the LLM framework to use these databases they should be properly vectorized. The process of vectorization ensures that the SCPI commands, DUT specifications and state files are indexed and searchable by the LLM for a retrieval during test configuration.

Detailed descriptions of the SCPI User Guide Breakdown, the Vectorization Process and the RAG approach are provided next. . SCPI User Guide Breakdown:

### 1. SCPI User Guide Breakdown

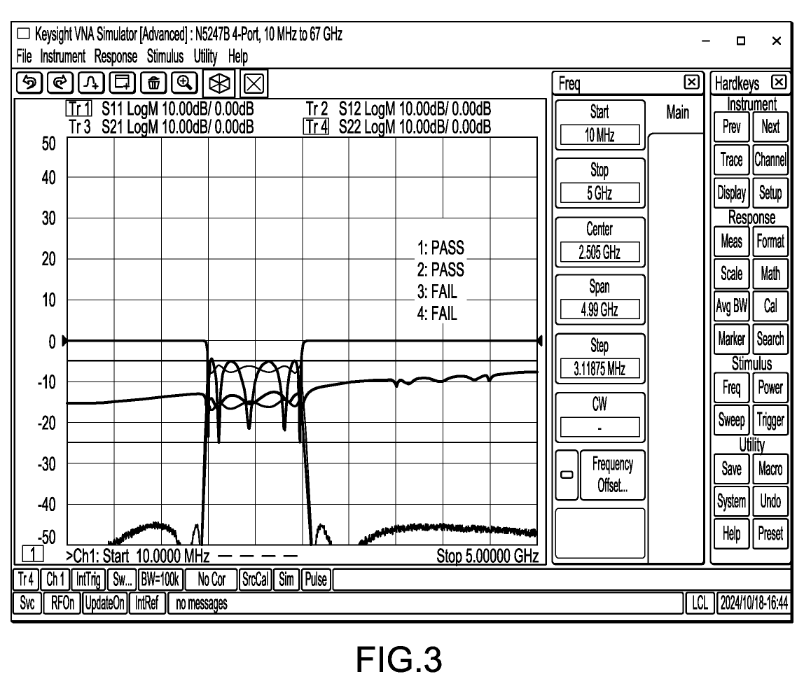

SCPI user guides for Network Analyzers contain detailed information on the commands used for controlling the device. FIG. 4 illustrates one of the examples of such documents:

These guides are broken down into smaller sections and commands are organized based on their hierarchy and functionality, for example:

1. General Commands: These include IEEE 488.2 common commands (*IDN?, *RST, *OPC?, etc.).

2. Measurement-Related Commands: Specific SCPI commands for performing various measurements (CALCulate, SENSe, etc.).

3. Error Correction and Calibration Commands: Commands like CALCulate:CORRection, SENS:CORR:CSET.

4. Data Access and Storage Commands: For storing, recalling, and querying measurement data (MMEMory, CALCulate:DATA).

Then each command is broken into vectorized units, indicating not only the command name but also additional parametrization:

1. Command Syntax: The exact command as issued to the VNA, e.g., CALCulate:CORRection:STATe ON.

2. Parameters: The required or optional parameters for the command, e.g., ON/OFF, <num>, FAST.

3. Description: A plain-text description of what the command does, the expected outcome, and relevant details.

4. Examples: Example SCPI command usage, e.g., CALCulate:CORRection:TYPE "Scalar Mixer Cal".

### 2. Vectorization Process

Using vectorization algorithms, this data is converted into vector representations and stored in a vector database.

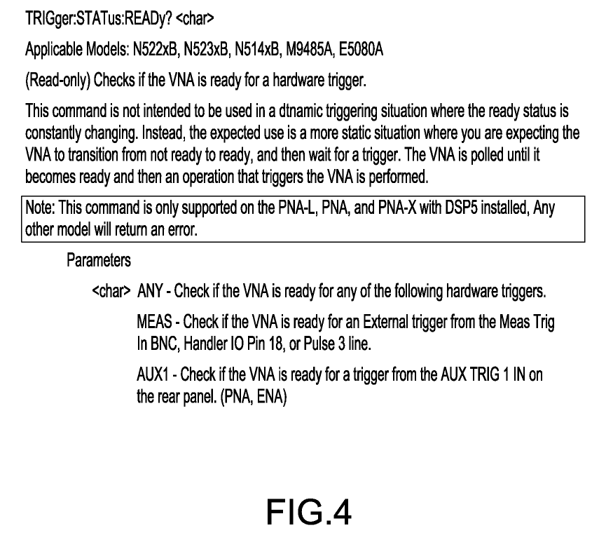

FIG. 5 illustrates the example of the vectorized frequency sweep SCPI command.

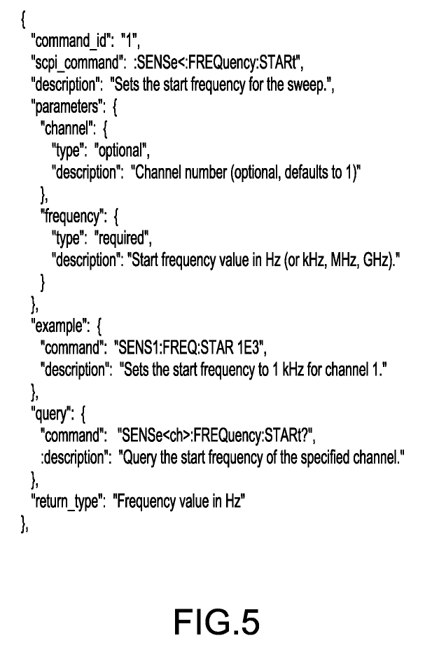

FIG. 6 illustrates an example of the vectorized state file database which contains previously used .csa files (binary), related SCPI-sequencies and short vectorized description for each state file.

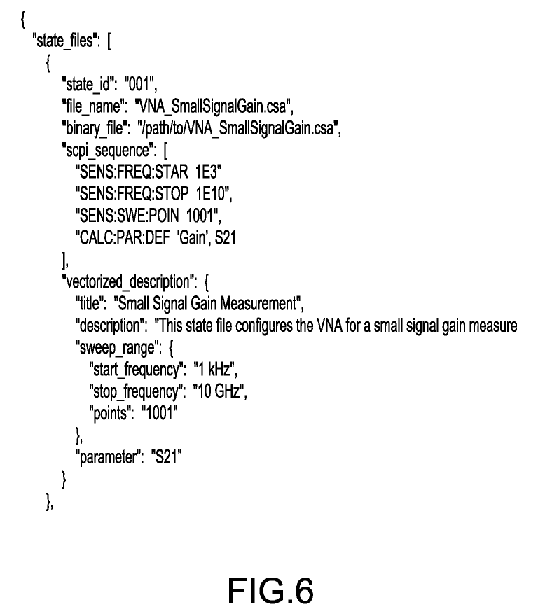

FIG. 7 illustrates an example of the DUT Specification record which was vectorized in a similar way and could be retrieved from the database. . Retrieve-then-Generate (RAG) Approach:

### 3. Retrieve-then-Generate RAG Approach

In the RAG approach, the LLM first retrieves relevant data (such as SCPI commands or specifications) from the vectorized SCPI guide database or DUT specifications database.

Once the relevant data is retrieved, the LLM generates an updated response with detailed context.

For example, when the LLM recognizes a DUT and needs to generate SCPI commands to configure the Network Analyzer, it retrieves the relevant command from the vectorized SCPI user guide and presents it in a sequence optimized for the measurement.

The LLM Server Deployment according to embodiments of the inventive concepts will now be described.

The LLM framework is deployed using a server-client architecture, with the LLM server managing requests and responses in real-time. The server handles API commands from the automation framework, processes these requests, and returns relevant information such as SCPI commands, DUT limits, and measurement parameters.

### Server-Client Architecture:

The LLM server runs on a dedicated machine or cloud infrastructure and processes all requests from PathWave Test Automation using API calls.

It is integrated with the SCPI command database (vectorized user guides), State File database and the DUT specification database (vectorized datasheets).

Each request is processed using generalized language models that have been setup to use RAG-methods specifically for DUT recognition, test setup configuration, and SCPI command generation.

### Cloud/Local Deployment Options:

The LLM server can be deployed locally within a lab environment or on the cloud, depending on the scalability and performance needs of the user.

Local deployment ensures low-latency communication with the test instruments, while cloud deployment allows for greater scalability and remote access to the public references.

Next, example prompts and responses at each stage of the framework will be described.

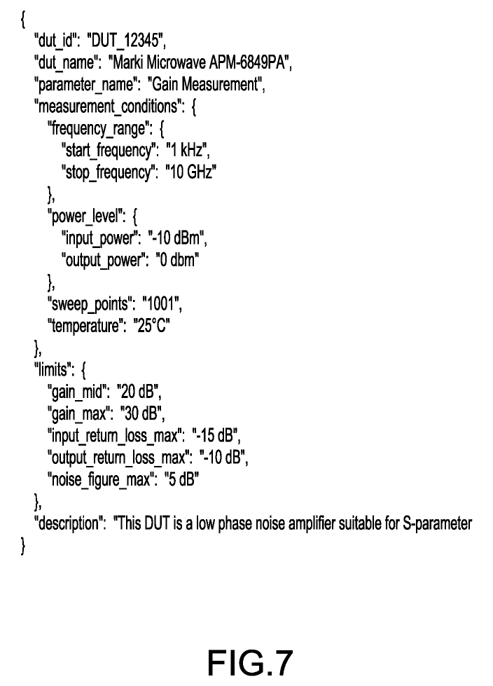

DUT Recognition (Capture and Identification Stage): Prompt: “Decode the DUT details including dimensions and part number” Response is shown in FIG. 8.

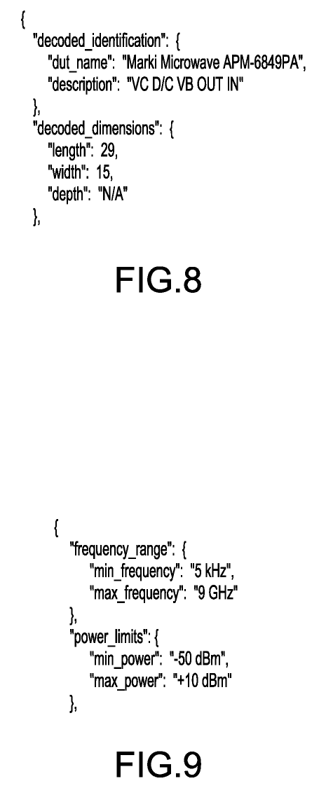

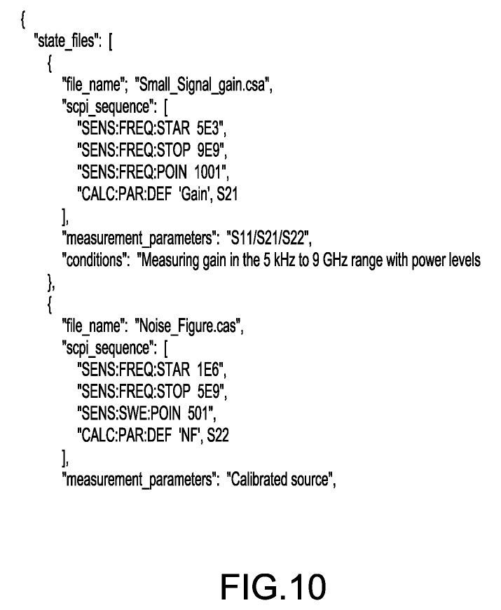

Measurement Condition Retrieval: Prompt: “Retrieve operational limits and sweep values for the Marki Microwave APM-6849PA [identified DUT]” Response is shown in FIG. 9. Prompt: “Retrieve state files, SCPI sequences, and associated measurement conditions for Marki Microwave APM-6849PA [identified DUT]” Response is shown in FIG. 10.

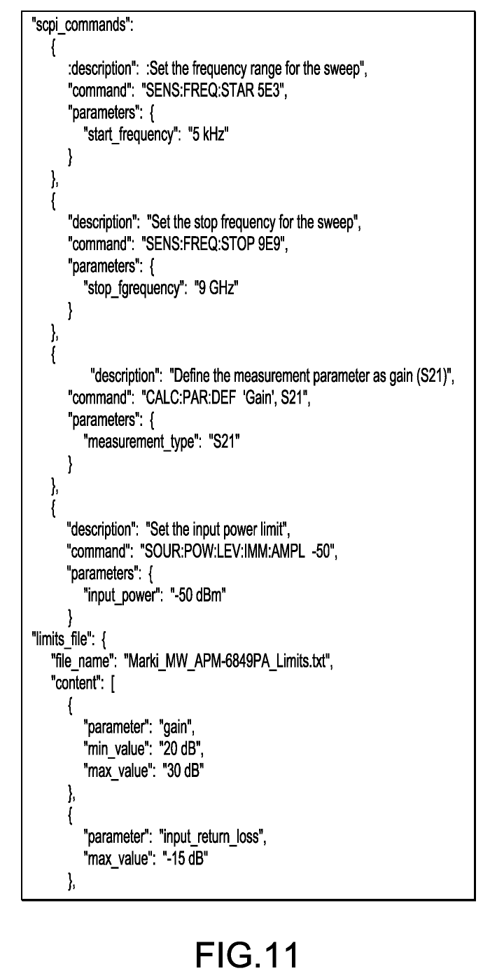

SCPI Command Generation: Prompt: “Generate SCPI commands for configuring the Network Analyzer based on saved measurement conditions, sweep definitions, and datasheet-defined limits.” Response is shown in FIG. 11.

Machine-user communication and interface integration will now be described as a three-step process.

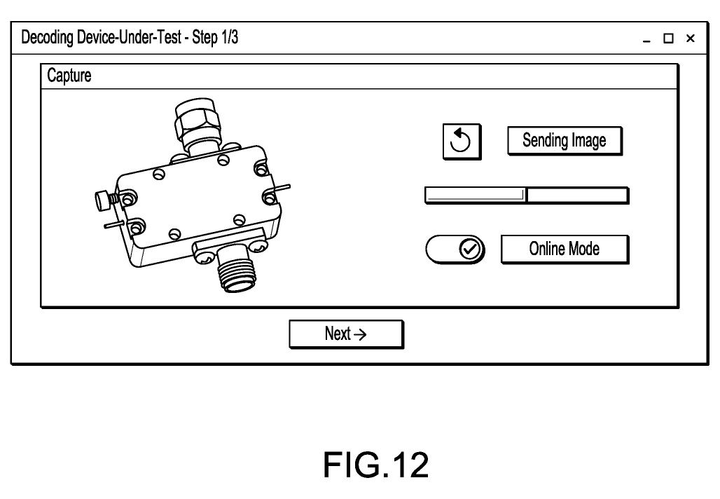

Step 1 – Capturing photos and initial DUT recognition, an example of which is shown in FIG. 12.

Capture Section (Top Left of FIG. 12): The captured image of the DUT is displayed in this section. The specific DUT shown is a Marki APM-6849PA device, and the system is in the process of recognizing its identifying features.

Sending Image (Top Right of FIG. 12): The system is waiting for the response from LLM framework marking the completion of the image pushing process and Image Analyzer response. The button " is highlighted, and a progress bar below it shows the recognition progress as the system analyzes the device's text, dimensions, and features.

Online Mode Indicator (Bottom of FIG. 12): This toggle indicates whether the system is in Online Mode, meaning it can access external databases and internet-based resources to retrieve DUT information. In this case, the indicator is switched on (green check), allowing the system to pull datasheets or specifications from the web if needed.

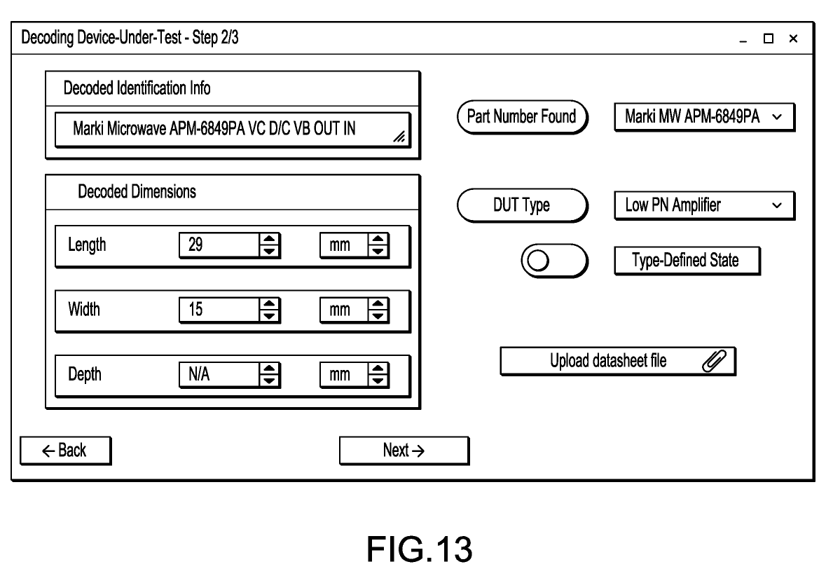

Step 2 – Reviewing decoded text and part number information, an example of which is shown in FIG. 13.

Decoded Identification Info (Top Section of FIG. 13): The system has successfully recognized all the text printed on the DUT. It shows Marki Microwave APM-6849PA as well as important labels such as VC, D/C, VB, OUT, and IN, which are part of the device’s specifications.

Decoded Dimensions (Middle Section of FIG. 13): The physical dimensions of the DUT have been extracted and are shown for review. The extraction is done by the camera module which should be calibrated (if this feature is needed) in advance for the proper position in front of the instrument screen. The user can adjust these values, if necessary, by using the input fields.

Part Number Found and DUT Type (Right Section of FIG. 13): The system has identified the part number and matched it to the specific Marki Microwave APM-6849PA component (based on the decoded text info and dimensions, comparing this info with the database recordings), using LLM. Additionally, the DUT Type has been recognized as a Low Phase Noise Amplifier. Both fields are dropdown menus, allowing the user to select or verify the correct part number and DUT type.

Type-Defined State Button: When switched on, the system automatically searches the database for a predefined state file associated with the selected DUT type (in this case, a Low PN Amplifier), not the part number. This feature should be used if the new part is being tested and no state files were ever created for that. In this case the level of the final customization could be lower (with no limits), but the user still does not need to manually define state files or SCPI commands. For example: if the DUT type is a Low PN Amplifier, the system will find a generalized state file from the database and automatically configure the instrument for a gain or noise figure test, without inputting sweep parametrization (or measurement conditions) specified during the next step. When the toggle is off, the system will look for custom limits for the mentioned part and custom state files / SCPI sequences.

Upload Datasheet Option (Bottom of FIG. 13): If the system is unable to retrieve all relevant details automatically or if the user wishes to add additional information, they can manually upload a datasheet file for the DUT by clicking the “Upload datasheet file” button. In this case LLM framework is using this file as an input, vectorize it with an automated prompt and extract measurement conditions from it.

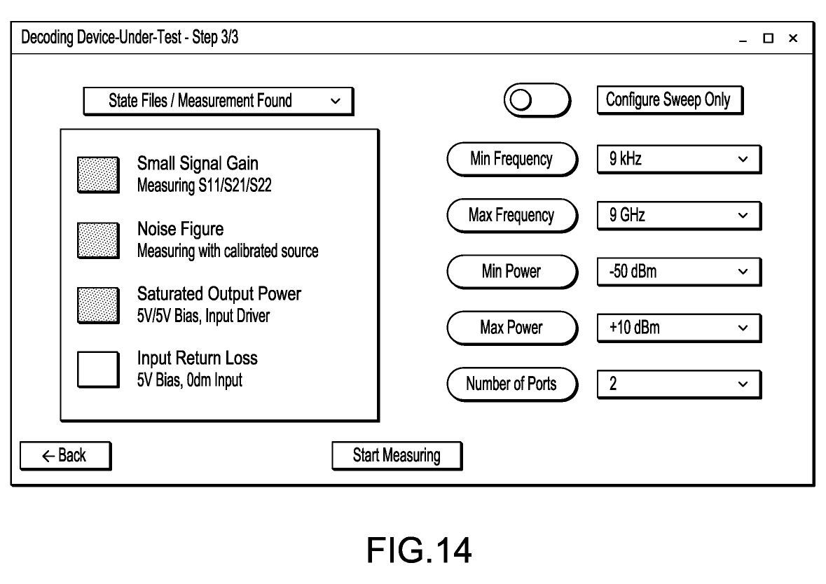

Step 3 – Configuring the final state file setup, and example of which is shown in FIG. 14.

State Files / Measurement Found (Left Section of FIG. 14): The system has successfully retrieved relevant State Files or pre-configured measurement setups for the recognized DUT. These state files are ready to be applied for the specific test being conducted. The user can select one or more state files from this list to apply to the test setup.

Measurement Parameters (Right Section of FIG. 14): The user can manually review or adjust key measurement parameters such as: Min Frequency: The minimum frequency for the test (e.g., 5 kHz). Max Frequency: The maximum frequency (e.g., 5 GHz). Min Power: The minimum power level for the test (e.g., -50 dBm). Max Power: The maximum power level (e.g., +10 dBm). Number of Ports: The number of test ports to be used (e.g., 2). These parameters correspond to the test conditions required for the DUT and are added to all the state files selected from the left list. In case none of the state files are selected (boxes will remain white instead of green) these parameters are just used to configure sweep ranges and the number of traces in the network analyzer.

Start Measuring Button (Bottom Section of FIG. 14): After reviewing the selected State Files and Measurement Parameters, the user can click the Start Measuring button to begin the test. This action sends the SCPI sequence execution using the PathWave Test Automation toolset to update network analyzer state files.

Configure Sweep Only (Top Section of FIG. 14): This button allows the user to update the frequency and power sweep settings when no matching part or state file is found. By enabling this feature, the user will reuse displayed the Min/Max Frequency and Min/Max Power values for a basic configuration, ensuring that the Network Analyzer is set up for the test. This simplifies the process when predefined settings are unavailable, allowing the user to configure the necessary sweep parameters and proceed with the measurement. When the toggle is off, the system defaults to using any retrieved state files or measurement configurations.

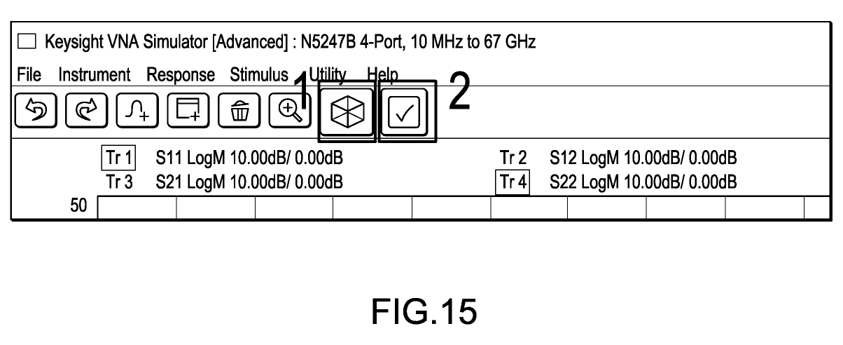

Next, referring to the interface example of FIG. 15, new interface elements of the Network Analyzer application will be described. In the example, the Network Analyzer is a Keysight ® Network Analyzer.

In this update to the Network Analyzer firmware, just two new visual elements may be added, allowing faster access to the Vision-Based DUT Recognition and Measurement Setup Framework. These icons are not intended to be used for 3^{rd} party integration as in this case the framework is running within the PathWave ® Test Automation environment as an executable test plan (precompiled application). Here’s what each element represents:

Start DUT Identification Button (Marked as Box 1 in FIG. 15):

This button initiates the DUT identification process. When clicked, the system starts the camera-based recognition of the connected DUT, followed by retrieving relevant specifications, datasheets, and configurations. This is the entry point for automating the entire measurement setup.

User can also setup the toolset for at automatic new capture after each saving data cycle to add the attached DUT photo every time the new measurement is initiated.

Connection and Limits Status Indicator (Marked as Box 2 in FIG. 15):

The checkmark indicates that the DUT is recognized and the DUT’s measurement limits (such as gain and noise figure values) have been loaded from the datasheet. It’s a visual confirmation that the system is ready to perform measurements according to the DUT’s specifications.

If the DUT is not recognized, the icon may change to a cross or X-sign over a black box, indicating a potential issue.

If the limits are not loaded, the icon may appear as a black box with white “L” letter, prompting the user to load the limits before starting the measurement.

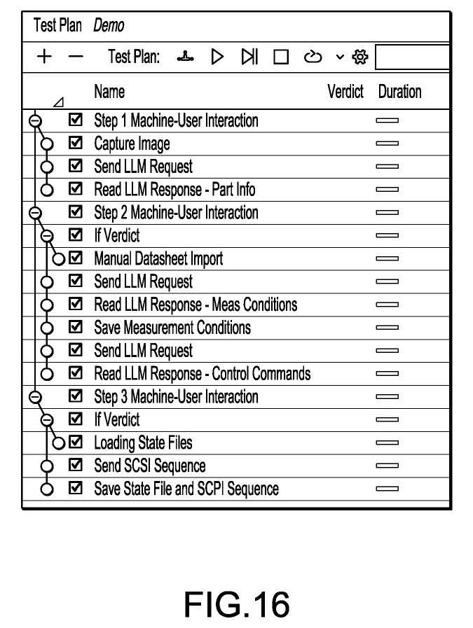

Lastly, an automated framework implementation using PathWave ® Test Automation will be described with reference to the Demo Test Plan of FIG. 16.

The Demo Test Plan shown is part of the PathWave Test Automation environment, displaying a detailed sequence for DUT (Device-Under-Test) identification, configuration, and measurement execution using an integrated LLM framework and SCPI command automation. . Step 1 of Machine-User Interaction:

### 1. Step 1 of Machine-User Interaction:

The user begins by interacting with the system. During this step the goal is to initiate the process of capturing the DUT’s image and to begin the recognition phase. . Capture Image:

### 2. Capture Image:

The system captures an image of the DUT using a camera (either external or internal), which will be analyzed in the next step.

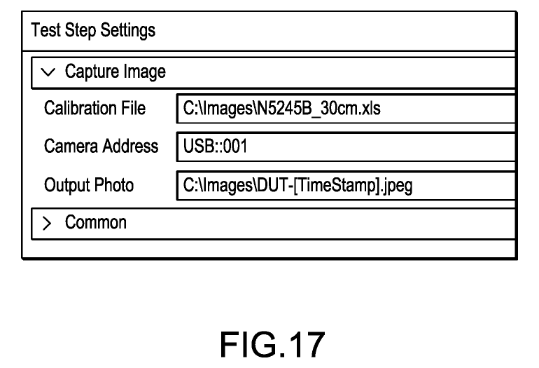

Referring to FIG. 17, test step is configured in the following way (note that the calibration file is used to convert measured pixels into physical length for certain DUT positions only). . Send LLM Request:

### 3. Send LLM Request:

The captured image is sent to the LLM framework for analysis, initiating the recognition of part numbers, dimensions, and other relevant identifiers.

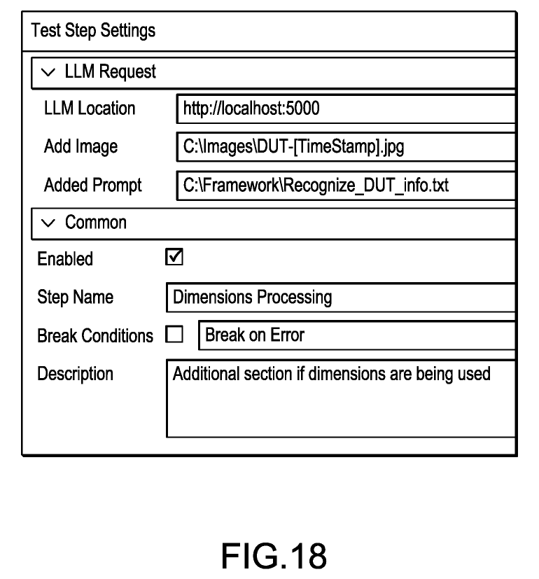

Referring to FIG. 18, based on the choice of online or offline mode the LLM server addresses change in the API call in the related Test Step settings. . Read LLM Response – Part Info:

### 4. Read LLM Response - Part Info:

The system reads the LLM response, which returns the recognized part information from the image analysis.

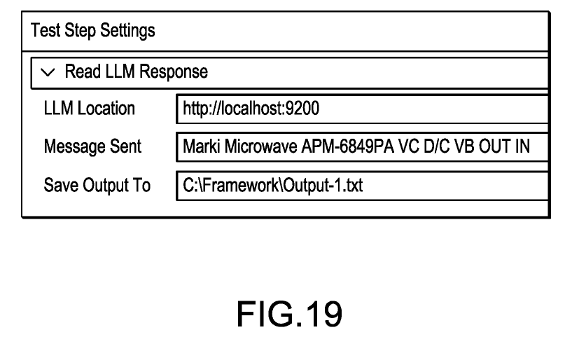

Test Settings are shown in FIG. 19. . Step 2 of Machine-User Interaction:

### 5. Step 2 of Machine-User Interaction

A second interaction occurs, where the user reviews the retrieved part information, dimensions and provides an additional datasheet data. . If Verdict:

### 6. If Verdict:

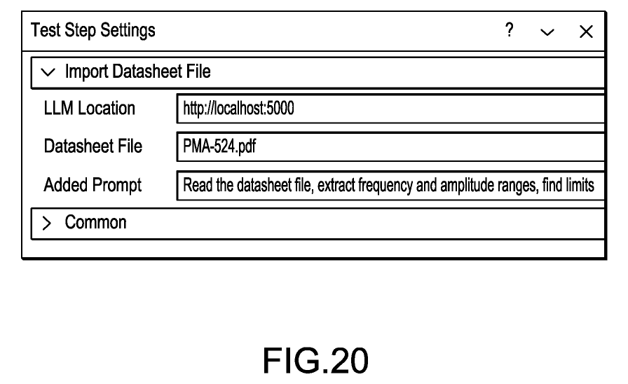

Determines whether the manual datasheet import mode is chosen – in this case the datasheet is parsed to the next LLM request as shown in FIG. 20. . Send LLM Request:

### 7. Send LLM Request:

A request is sent to the LLM to extract measurement conditions from the datasheet, databased retrieved part information or from a dedicated web-search through a Copilot LLM-interaction mode. . Read LLM Response – Measurement Conditions:

### 8. Read LLM Response - Measurement Conditions:

The system reads the LLM response, which returns the extracted measurement conditions needed for network analyzer sweeps such as frequency ranges, power limits, etc. . Save Measurement Conditions:

### 9. Save Measurement Conditions:

These measurement conditions are saved within the system for use in configuring the instrument later in the process. This step is needed to save both sweep parametrization for Network Analyzer and limits for the particular DUT. 0. Send LLM Request:

### 10. Send LLM Request:

The system a final sends a request to retrieve the SCPI commands required for configuring the instrument based on the preloaded SCPI Programming Guide for specific instrument models, also checks if there were any saved state files. 1. Read LLM Response – State Files Commands:

### 11. Read LLM Response - State Files Commands:

The LLM returns the SCPI commands and state files needed to properly configure the instrument for testing the DUT. 2. Step 3 of Machine-User Interaction:

### 12. Step 3 of Machine-User Interaction:

In this interaction, the user can review the SCPI commands and state files, ensuring that everything is correct before moving forward. Also, the measurement parametrization for NA sweeps is being displayed here. 3. If Verdict:

### 13. Verdict:

The system checks whether the previous state files should be loaded. 4. Send SCPI Sequence:

### 14. Send SCPI Sequence:

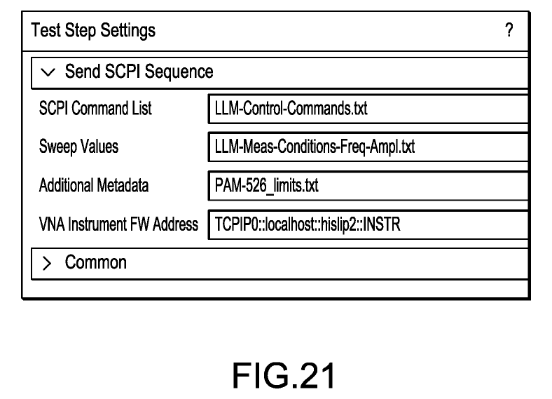

Referring to FIG. 21, the SCPI sequence is sent to the Network Analyzer, configuring the instrument to carry out the measurement as per the DUT’s requirements. 5. Save State Files and SCPI:

### 15. Save State Files and SCPI:

As soon as SCPI commands were sent to the Network Analyzer application the generated sequence can be saved as well as the state file from the application. Each state file is thus duplicated with the SCPI sequence alternative and has a full definition.

The inventive concepts encompass systems and methods for real-time channel model adaptation based on receiver feedback and performance metrics as described above. Further, the inventive concepts encompass non-transitory computer readable storage media having instructions stored therein that when executed by a processor cause the processor to carry out the methods of the inventive concepts. The memory storing the instructions can comprise random access memory (RAM), read only memory (ROM), optical read/write memory, cache memory, magnetic read/write memory, flash memory, and/or any other non-transitory computer readable storage medium.

While the invention has been illustrated and described in detail in the drawings and foregoing description, such illustration and description are to be considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims. While representative embodiments are disclosed herein, one of ordinary skilledf in the art will appreciate that many variations that are in accordance with the present teachings are possible and remain within the scope of the appended claim set. The invention therefore is not to be restricted except within the scope of the appended claims.

What is claimed is:

1. A system for automated device-under-test (DUT) recognition and measurement setup, comprising:
a camera configured to capture an image of a DUT;
an image analyzer configured to process the captured image and extract DUT characteristics;
a large language model (LLM) system configured to identify the DUT based on the extracted characteristics and retrieve DUT specifications;
a command processing module configured to generate measurement setup commands based on the retrieved DUT specifications; and
a network analyzer configured to execute the measurement setup commands for testing the DUT.

2. The system of claim 1, wherein the LLM system is further configured to retrieve measurement conditions for the DUT from a datasheet or database.

3. The system of claim 2, wherein the measurement conditions include frequency ranges, power limits, and operational parameters specific to the identified DUT.

4. The system of claim 1, wherein the command processing module is further configured to generate SCPI (Standard Commands for Programmable Instruments) commands based on the retrieved DUT specifications.

5. The system of claim 4, wherein the command processing module is further configured to access a command repository containing SCPI command syntax for various network analyzers.

6. The system of claim 1, further comprising a user interface configured to display the extracted DUT characteristics and allow user confirmation or modification of the identified DUT.

7. The system of claim 6, wherein the user interface is further configured to display and allow user selection of pre-configured measurement setups or state files associated with the identified DUT.

8. A method for automated device-under-test (DUT) recognition and measurement setup, comprising:
capturing an image of a DUT using a camera;
analyzing the captured image to extract DUT characteristics;
identifying the DUT and retrieving DUT specifications using a large language model (LLM) system based on the extracted characteristics;
generating measurement setup commands based on the retrieved DUT specifications; and
configuring a network analyzer using the generated measurement setup commands for testing the DUT.

9. The method of claim 8, further comprising retrieving measurement conditions for the DUT from a datasheet or database using the LLM framework.

10. The method of claim 9, wherein the measurement conditions include frequency ranges, power limits, and operational parameters specific to the identified DUT.

11. The method of claim 8, wherein generating measurement setup commands comprises generating SCPI (Standard Commands for Programmable Instruments) commands based on the retrieved DUT specifications.

12. The method of claim 11, further comprising accessing a command repository containing SCPI command syntax for various network analyzers.

13. The method of claim 8, further comprising displaying the extracted DUT characteristics on a user interface and allowing user confirmation or modification of the identified DUT.

14. The method of claim 13, further comprising displaying and allowing user selection of pre-configured measurement setups or state files associated with the identified DUT.

15. A non-transitory computer-readable medium storing instructions that, when executed by a processor, cause the processor to perform operations for automated device-under-test (DUT) recognition and measurement setup, the operations comprising:
receiving a captured image of a DUT;
extracting DUT characteristics from the captured image;
identifying the DUT and retrieving DUT specifications using a large language model (LLM) system based on the extracted characteristics;
generating measurement setup commands based on the retrieved DUT specifications; and
sending the generated measurement setup commands to a network analyzer for configuring the network analyzer to test the DUT.

16. The non-transitory computer-readable medium of claim 15, wherein the operations further comprise retrieving measurement conditions for the DUT from a datasheet or database using the LLM framework.

17. The non-transitory computer-readable medium of claim 16, wherein the measurement conditions include frequency ranges, power limits, and operational parameters specific to the identified DUT.

18. The non-transitory computer-readable medium of claim 15, wherein generating measurement setup commands comprises generating SCPI (Standard Commands for Programmable Instruments) commands based on the retrieved DUT specifications.

19. The non-transitory computer-readable medium of claim 18, wherein the operations further comprise accessing a command repository containing SCPI command syntax for various network analyzers.

20. The non-transitory computer-readable medium of claim 19, wherein the operations further comprise displaying the extracted DUT characteristics on a user interface and allowing user confirmation or modification of the identified DUT.
